(19) United States
(12) Patent Application Publication
(10) Pub. No.: US 2012/0035055 A1
(43) Pub. Date: Feb. 9, 2012

(54) RE1Ba2Cu3O7-z SUPERCONDUCTOR

(76) Inventors: Masataka IWAKUMA, Fukuoka-shi (JP); Akira Ibi, Tokyo (JP); Teruo Izumi, Tokyo (JP); Yuh Shiohara, Tokyo (JP)

(21) Appl. No.: 13/154,684

(22) Filed: Jun. 7, 2011

(30) Foreign Application Priority Data
Aug. 5, 2010 (JP) 2010-176685

(51) Int. Cl. H01L 39/12; H01F 6/00

(52) U.S. Cl. 505/126; 505/211; 505/100; 335/216

(57) ABSTRACT

Problem: To provide an REBCO superconductor which has electromagnetic properties of an extremely small magnetization in a DC magnetic field or an extremely small pinning loss in a fluctuating magnetic field and thereby enable production of a REBCO superconducting wire with an extremely small magnetization and pinning loss.

Solution to Problem: A RE₁Ba₂Cu₃O_{7-z} superconductor characterized by having a magnetization-zero-region on its magnetization curve, wherein in the magnetization-zero-region a rate of change of magnetization remains at about zero near zero magnetization, the magnetization curve is formed when an external magnetic field turns from an increase to a decrease or from a decrease to an increase, and RE is one or more of Y, Gd, Nd, Sm, Eu, Yb, Pr, and Ho.

### TECHNICAL FIELD

The present invention relates to a superconductor which shows specific electromagnetic properties at a superconducting temperature range in a DC magnetic field and AC magnetic field.

### BACKGROUND ART

An RE₁Ba₂Cu₃O_{7-z} superconductor (RE: one or more of Y, Gd, Nd, Sm, Eu, Yb, Pr, and Ho. Below, RE₁Ba₂Cu₃O_{7-z} sometimes described as “REBCO”) has a small reduction of the critical current density Jc (below, sometimes simply referred to as “Jc”) in a high magnetic field region, so is being focused on as a next generation superconducting wire material (see PLTs 1 and 2 and NPLTs 1 to 6).

An REBCO superconductor has a perovskite-type crystal structure. It has a coherence length along a c axis much shorter than the coherence lengths along the a axis and b axis, so a large anisotropy is shown in the superconducting property.

The superconducting property of wire provided with a thin film of an REBCO superconductor (hereinafter sometimes referred to as an “REBCO superconducting wire”) is related to the CuO₂ planes of the crystal structure (see NPLT 4). To increase the critical current density Jc of an REBCO superconducting wire, it is necessary to form a highly oriented (a axis and b axis) REBCO superconductor thin film on the wire substrate (see FIG. 2).

At the present time, a REBCO superconducting wire with a critical current of 280 A or more by a 1 cm width and with a length of 1 km or more is being obtained. Furthermore, for practical application, much research is underway on the improvement of the Jc and/or anisotropy in Jc. However, there is little research being conducted on the magnetic properties of REBCO superconducting wire, in particular the pinning loss.

The anisotropy of the pinning loss in REBCO superconducting wire is also dependent on the magnitude of the anisotropy in the Jc, but is mainly mostly related to the shape (aspect ratio) of the superconducting layer (see NPLT 7). The larger the aspect ratio, the greater the anisotropy of the pinning loss. The pinning loss which occurs due to an external magnetic field which is perpendicular to the superconducting layer of the REBCO superconducting wire is larger than the pinning loss which occurs due to a magnetic field which is parallel to the superconducting layer.

In a coil which is produced by an REBCO superconducting wire, the AC loss which occurs due to a magnetic field which is perpendicular to the superconducting layer accounts for the majority of the total heat load which occurs in a superconducting system (see NPLTs 7 to 9). Accordingly, reduction of the AC loss is becoming the more important task in actual application of REBCO superconducting wire to electrical equipment.

The AC loss, more precisely speaking, is the sum of the pinning loss and the coupling current loss, but in the case of a superconducting system comprised of REBCO superconducting wire bundled together, the coupling current loss can be substantially ignored (see NPLTs 10 to 11), so when applying a REBCO superconducting wire to AC equipment, reduction of the pinning loss in an REBCO superconducting wire becomes the most important task.

The inventors propose the method of reducing the pinning loss when using an REBCO superconducting wire to produce a solenoid coil by forming a plurality of grooves in the superconducting layer (see PLT 3 and NPLT 9), but if forming a large number of grooves in a superconducting layer, the critical current Ic of the superconducting layer falls, so there is a limit to the reduction of the pinning loss.

On the other hand, when applying superconducting wire to a accelerator in the field of high energy physics, medical equipment (NMR, heavy particle accelerator for the treatment of cancer, etc.), etc., compared to the magnitude of the magnetic field which the superconducting coil generates, the change along with time in the disturbance of the magnetic field due to magnetization of the superconducting wire, which is caused by the flux creep phenomenon, should be relatively small, so a superconducting wire is required to have not only a small pinning loss, but also a small magnetization itself.

### CITATION LIST

### Patent Literature

PLT 1: Japanese Patent Publication (A) No. 2009-289666
PLT 2: Japanese Patent Publication (A) No. 2009-164010
PLT 3: Japanese Patent Publication (A) No. 2007-141688

### Non-Patent Literature

NPLT 1: Foltyn L. S. R. et al., 2007 Nat. Mater. 6, 631-42
NPLT 2: Kang S. et al., 2006 Science 311, 1911-4
NPLT 3: Shiohara Y, et al., 2007 Physica C 463-465, 1-6
NPLT 4: Calestani G., 1996 High Temperature Superconductivity Models and Measurements (Singapore: World Scientific), pp. 1-40
NPLT 5: Kakimoto K. et al., 2003 Physica C 392-396, 783-9
NPLT 6: Selvamanickam V. et al., 2009 Progress in SuperPower's 2G HTS Wire Development Program US Department of Energy Superconductivity for Electric Systems Peer Review, Alexandria, Va., USA, 4 August
NPLT 7: Iwakuma M. et al., 2005 IEEE Trans. Appl. Supercond. 15, 1562-5
NPLT 8: Iwakuma M. et al., 1999 IEEE Trans. Appl. Supercond. 11, 1482-5
NPLT 9: Iwakuma M. et al., 2009 Physica C 469, 1726-32
NPLT 10: Iwakuma M. et al., 2002, Supercond. Sci. Technol. 15, 1525-1536
NPLT 11: Iwakuma M. et al., 2002, Supercond. Sci. Technok. 15, 1537-1546

### SUMMARY OF INVENTION

### Technical Problem

As explained above, when applying REBCO superconducting wire to AC equipment, to greatly reduce the AC loss, the REBCO superconducting wire is required to have an extremely small pinning loss. Further, when applying REBCO superconducting wire to DC equipment, to greatly reduce the change in the magnetic field over time, the REBCO superconducting wire is required to have extremely small pinning loss and magnetization.

Therefore, the present invention has as its object the provision of an REBCO superconductor which has electromagnetic properties of an extremely small magnetization and pinning loss in a magnetic field and thereby enables production of a REBCO superconducting wire with an extremely small magnetization and pinning loss.

### Solution to Problem

The inventors intensively studied the magnetization properties of an REBCO superconductor and as a result discovered that the magnetization curve of an REBCO superconductor exhibits distinctive behavior in a magnetic field.

The present invention was made based on the above discovery and has as its gist the following:

(1) A RE₁Ba₂Cu₃O_{7-z} superconductor characterized by having a magnetization-zero-region on its magnetization curve, wherein in the magnetization-zero-region a rate of change of magnetization remains at about zero near zero magnetization, the magnetization curve is formed when an external magnetic field turns from an increase to a decrease or from a decrease to an increase, and RE is one or more of Y, Gd, Nd, Sm, Eu, Yb, Pr, and Ho.

(2) The RE₁Ba₂Cu₃O_{7-z} superconductor as set forth in (1) characterized in that a magnetization difference (ΔM) of the magnetization-zero-region does not correspond one-to-one to a magnitude of a critical current density, a wire width, or, when divided into filaments, the filament widths.

(3) The RE₁Ba₂Cu₃O_{7-z} superconductor as set forth in (1) or (2) characterized in that the magnetization curve has a magnetization abrupt drop zone in which the magnetization abruptly drops when the external magnetic field reverses in direction.

(4) The RE₁Ba₂Cu₃O_{7-z} superconductor as set forth in (1) or (2) characterized in that the magnetization curve has the magnetization-zero-region extending over the entire curve.

(5) The RE₁Ba₂Cu₃O_{7-z} superconductor characterized in that a phenomenon described in one or more of (1) to (2) becomes pronounced, whereby the magnetization curve does not swell much at all when the external magnetic field changes, that is, follows substantially the same magnetization path when the external magnetic field changes.

(6) The RE₁Ba₂Cu₃O_{7-z} superconductor as set forth in any one of (1) to (2) characterized in that the RE is Gd.

(7) The RE₁Ba₂Cu₃O_{7-z} superconductor as set forth in any one of (1) to (2) characterized in that the RE is Y.

(8) The RE₁Ba₂Cu₃O_{7-z} superconductor as set forth in any one of (1) to (2) characterized in that the RE is Y₁₋ₓGdₓ (0<x<1).

(9) The RE₁Ba₂Cu₃O_{7-z} superconductor as set forth in any one of (1) to (2) characterized in that an in-plane crystal alignment of the RE₁Ba₂Cu₃O_{7-z} superconductor is less than 6.0°.

(10) The RE₁Ba₂Cu₃O_{7-z} superconductor as set forth in any one of (1) to (2) characterized in that the phenomena described one or more of the (1) to (5) occurs in accordance with the principle that the CuO₂ superconducting planes which are mainly responsible for transporting superconducting current mainly extend two dimensionally and are present in a plurality of planes at certain plane intervals and that having the magnetic flux or quantized magnetic flux penetrate between the CuO₂ planes results in a lower energy of the system and greater stability by the amount of difference of the superconducting condensation energy compared with having the quantized magnetic flux have a perpendicular component to the CuO₂ planes or enter perpendicular to or at a slant from the CuO₂ planes.

(11) A RE₁Ba₂Cu₃O_{7-z} superconductor characterized in that a phenomenon of a small magnetization and/or a phenomenon of a small pinning loss occurs in accordance with the principle that the CuO₂ superconducting planes which are mainly responsible for transporting superconducting current mainly extend two dimensionally and are present in a plurality of planes at certain plane intervals and that having the magnetic flux or quantized magnetic flux penetrate between the CuO₂ planes results in a lower energy of the system and greater stability by the amount of difference of the superconducting condensation energy compared with having the quantized magnetic flux have a perpendicular component to the CuO₂ planes or enter perpendicular to or at a slant from the CuO₂ planes.

(12) A superconductor characterized in that a phenomenon of a small magnetization and/or a phenomenon of a small pinning loss occurs in accordance with the principle that the thin superconducting planes which are mainly responsible for transporting superconducting current mainly extend two dimensionally and are present in a plurality of planes at certain plane intervals and that having the magnetic flux or quantized magnetic flux penetrate between the superconducting planes results in a lower energy of the system and greater stability by the amount of difference of the superconducting condensation energy compared with having the quantized magnetic flux have a perpendicular component to the superconducting planes or enter perpendicular to or at a slant from the superconducting planes.

### Advantageous Effect of Invention

According to the present invention, it is possible to provide a REBCO superconductor which has electromagnetic properties of an extremely small magnetization and pinning loss in a fluctuating or stationary magnetic field and thereby enables production of a REBCO superconducting wire with an extremely small magnetization and pinning loss.

### BRIEF DESCRIPTION OF DRAWINGS

FIG. 1 is a view which schematically shows the layer structure of a test wire B which forms a Gd₁Ba₂Cu₃O₇₋ₓ superconductor as a superconducting layer.

FIG. 2 is a view which shows the alignment of crystals which form the superconducting layer.

FIG. 3 is a view which shows a pick-up coil method which uses a saddle-shaped pick-up coil.

FIG. 4 is a view which shows modes of magnetization. (a) shows a mode of magnetization substantially along a c axis of the crystals (M_{//c}), while (b) shows a mode of magnetization substantially along an a axis and b axis of the crystals (M_{//ab}).

FIG. 5 is a view showing the results of measurement of the magnetization properties of a test wire A at a maximum magnetic field amplitude Bm: 1.7T or 2.0T. (a) shows the magnetization curves which were measured at T=77K, θ=90°, 45°, 30°, and 15°, and a maximum magnetic field amplitude Bm: 1.7T, (b) shows the magnetization curves which were measured at T=64K, θ=90°, 45°, 30°, and 15°, and a maximum magnetic field amplitude Bm: 1.7T, (c) shows the magnetization curve which was measured at T=64K, θ=15°, and a maximum magnetic field amplitude Bm: 2.0T, and (d) shows the enlarged right end of the magnetization curve which was measured at T=64K, θ=15°, and a maximum magnetic field amplitude Bm: 2.0T.

FIG. 6 is a view showing the results of measurement of the magnetization properties of the test wire A at a maximum magnetic field Be: 4.8T. (a) shows a magnetization curve which was measured at T=64K and θ=15°, (b) shows a magnetization curve which was measured at T=35K and θ=15°, and (c) shows a magnetization curve which was measured at T=35K and θ=45°.

FIG. 7 is a view showing the results of measurement of the magnetization properties of the test wire B at a maximum magnetic field amplitude Bm: 1.7T, (a) shows magnetization curves which were measured at T=77K and θ=90°, 45°, 30°, and 15°, (b) shows magnetization curves which were measured at T=64K and θ=90°, 85°, 80°, 75°, 70°, 65°, 60°, 55°, 50°, 45°, 40°, 35°, 30°, 25°, 20°, and 15°, (c) shows a magnetization curve which was measured at T=64K and θ=15°, and (d) shows top right ends of magnetization curves which were measured at T=45K and θ=90°, 80°, 70°, 60°, 50°, 40°, 30°, and 20°.

FIG. 8 is a view showing the results of measurement of the magnetization properties of the test wire B at T=45K and 35K, a maximum magnetic field amplitude Bm: 1.7T, and θ changed in a range of 10 to 90°. (a) shows the magnetization curves which were measured at T=45K, while (b) shows the magnetization curves which were measured at T=35K.

FIG. 9 is a view showing the results of measurement of the magnetization properties of the test wire B at changed T, θ, and maximum magnetic field amplitudes Bm. (a) shows the magnetization curve which was measured at T=77K, θ=15°, and a maximum magnetic field Be: 2.8T, (b) shows the magnetization curve which was measured at T=64K, θ=15°, and a maximum magnetic field Be: 4.8T, and (c) shows the magnetization curve which was measured at T=35K, θ=60°, and a maximum magnetic field Be: 4.8T.

FIG. 10 is a view showing the relationship, measured for a test wire A and the test wire B, between the maximum magnetic field amplitude Bm (T) and pinning loss (J/m³ cycle). (a) shows the results of measurement, for the test wire A, at T=77K and θ=90°, 45°, 30° and 15°, while (b) shows the results of measurement, for the test wire B, at T=35K and θ=90°, 60°, 45°30°, 15°, and 10°.

FIG. 11 shows the relationship, measured for the test wire B, between the maximum magnetic field amplitude Bm (T) and the pinning loss (J/m³ cycle). (a) shows the results of measurement at T=77K and θ=15° (corresponding to FIG. 9(a)), (b) shows the results of measurement at T=64K and θ=15° (corresponding to FIG. 9(b)), and (c) shows the results of measurement at T=35K and θ=60° (corresponding to FIG. 9(b)).

FIG. 12 is a view which schematically shows a mode of penetration of a quantized magnetic flux (fluxoid) to the REBCO superconducting layer (CuO₂ planes). (a) shows the mode of penetration to the REBCO superconducting layer perpendicularly, while (b) shows the mode of penetration to the REBCO superconducting layer in parallel.

FIG. 13 is a view showing one mode of alignment of the superconducting crystals.

### DESCRIPTION OF EMBODIMENTS

The RE₁Ba₂Cu₃O_{7-z} superconductor of the present invention (below, sometimes referred to as “the superconductor of the present invention”) is characterized by having a “magnetization-zero-region” on its magnetization curve, wherein in the “magnetization-zero-region” a rate of change of magnetization remains at about zero near zero magnetization (this will be explained later), and the magnetization curve is formed when an external magnetic field turns from an increase to a decrease or from a decrease to an increase. Here, RE is one or more of Y, Gd, Nd, Sm, Eu, Yb, Pr, and Ho.

Further, the superconductor of the present invention is characterized in that the magnetization curve has a “magnetization abrupt drop zone” where the magnetization abruptly drops when the external magnetic field reverses in direction (this will also be explained later).

Further, the superconductor of the present invention is characterized in that a specific phenomenon is manifested where the magnetization curve follows substantially the same magnetization path and does not expand at the time of a change including reversal of direction of the external magnetic field (this will also be explained later).

Using a Y₁Ba₂Cu₃O_{7-z} superconductor (RE=Y) and Gd₁Ba₂Cu₃O_{7-z} superconductor (RE=Gd) as examples, the specific electromagnetic properties (magnetization curve) of the superconductor of the present invention will be explained.

Using the RR (Reel-to-Reel) method using the IBAD (ion-beam assisted deposition) method and PLD (pulsed laser deposition) method, test wires having a Y₁Ba₂Cu₃O_{7-z} superconductor (RE=Y) and Gd₁Ba₂Cu₃O_{7-z} superconductor (RE=Gd) as a superconducting layer were produced (see NPLT 5).

Table 1 shows the specifications and properties of the produced test wire A and test wire B. In the table, BZO means the BaZrO₃ (ordinary conducting phase) which is dispersed in the superconducting layer. BaZrO₃ functions as a pinning center which traps the magnetic flux. Further, in the table, Δφ is the in-plane alignment of the superconducting layer crystals (average angle of disturbance of alignment of crystals in a-b plane direction shown in FIG. 2 and FIG. 13), while Δω is the alignment in the direction perpendicular to the a-b plane (average angle of disturbance of alignment in direction perpendicular to a-b plane direction).

TABLE 1

| | Test wire A | Test wire B |
|---|---|---|
| Critical current | 234 A | 254 A |
| Ic(77K) | | |
| Critical current density | 1.02 × 10¹⁰ A/m² | 2.12 × 10¹⁰ A/m² |
| Jc(77K) | | |
| Width | 10 mm | 10 mm |
| Stabilizing layer | Ag(20 μm) | Ag(10 μm) |
| Superconducting layer | YBCO(2.3 μm) | GdBCO + BZO(1.2 μm) |
| Intermediate layer | CeO₂(0.4 μm) | CeO₂(0.4 μm) |
| | Gd₃Zr₃O₇(0.8 μm) | Gd₃Zr₃O₇(0.8 μm) |
| Substrate | Hastelloy(100 μm) | Hastelloy(100 μm) |
| Δφ | 5.4° | 3.0° |
| Δω | 2.9° | 3.3° |

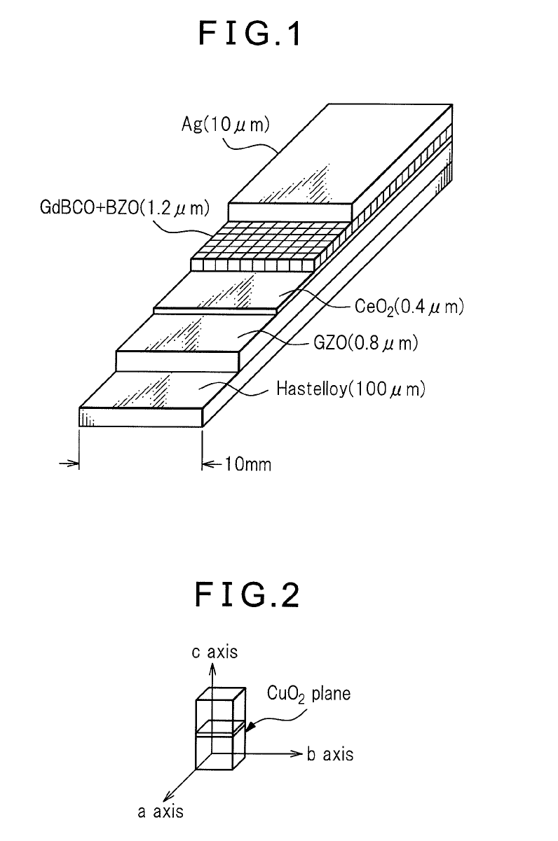

FIG. 1 schematically shows a layer structure of a test wire B. The superconducting layer (GdBCO+BZO) is formed on an intermediate layer (CeO₂, thickness: 0.4 μm), while a stabilizing layer (Ag, thickness 10 μm) which stabilizes the superconducting property is formed on the superconducting layer.

FIG. 2 shows the crystal alignment of the superconducting layer (GdBCO+BZO). The crystals have an a axis and b axis parallel to the plane of the wire substrate and have a c axis perpendicular to the wire substrate. That is, the CuO₂ planes responsible for the superconducting mechanism are present parallel to the plane of the wire substrate, so to maintain superior superconducting property, the crystals have to be aligned to a high degree. Therefore, Δφ and Δω are both preferably as small as possible.

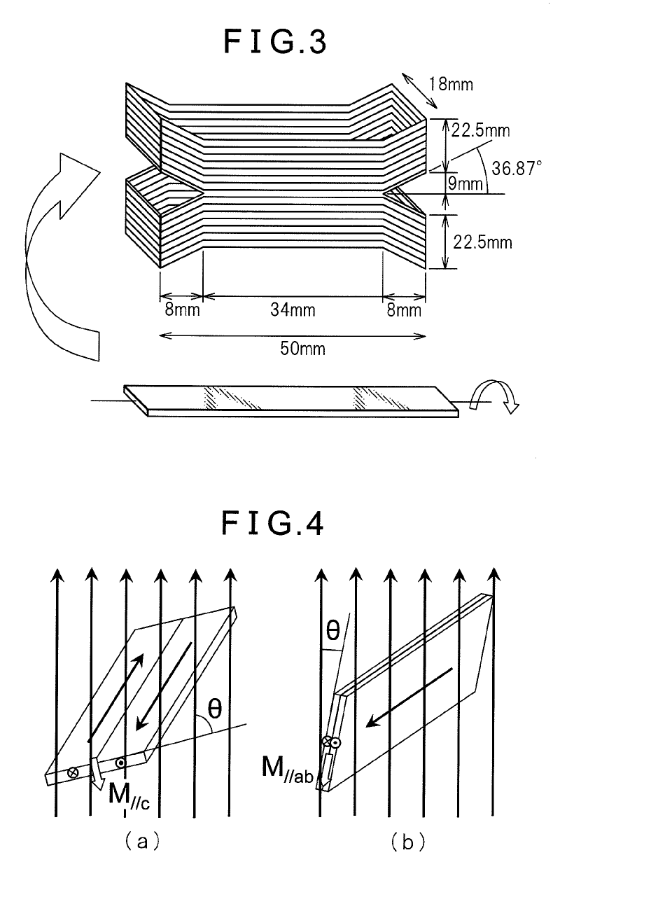

The inventors measured the magnetization curves of the test wire A and the test wire B in the temperature range where the superconducting phenomenon is manifested. FIG. 3 shows a saddle-type pick-up coil used for measurement of the magnetization by the pick-up coil method. Note that, in the figure, the dimensions of the saddle-type pick-up coil are shown. The test wire 2 was inserted into the center part of the saddle-type pick-up coil 1, then the test wire 2 was rotated by 0 degrees about the longitudinal direction axis and measured for magnetization.

FIG. 4 shows the superconducting shielding current induced by fluctuations in the external magnetic field and the mode of magnetization due to the same (magnetization is defined as the magnitude of the magnetic moment based on the shielding current converted to the unit volume of the superconductor). FIG. 4(a) shows the mode of magnetization substantially along the c axis of the crystals (M_{//c}), while FIG. 4(b) shows the mode of magnetization substantially along the a axis and b axis of the crystals (M_{//ab}).

The test wire was cooled to 30 to 77K and the magnetization was measured while changing the angle θ of application of the magnetic field to the broad side of the wire between 10 to 90° in range. 0 is 0° when the application is parallel to the broad side of the wire and is 90° when perpendicular. The magnetic field was applied up to a maximum of about 5T.

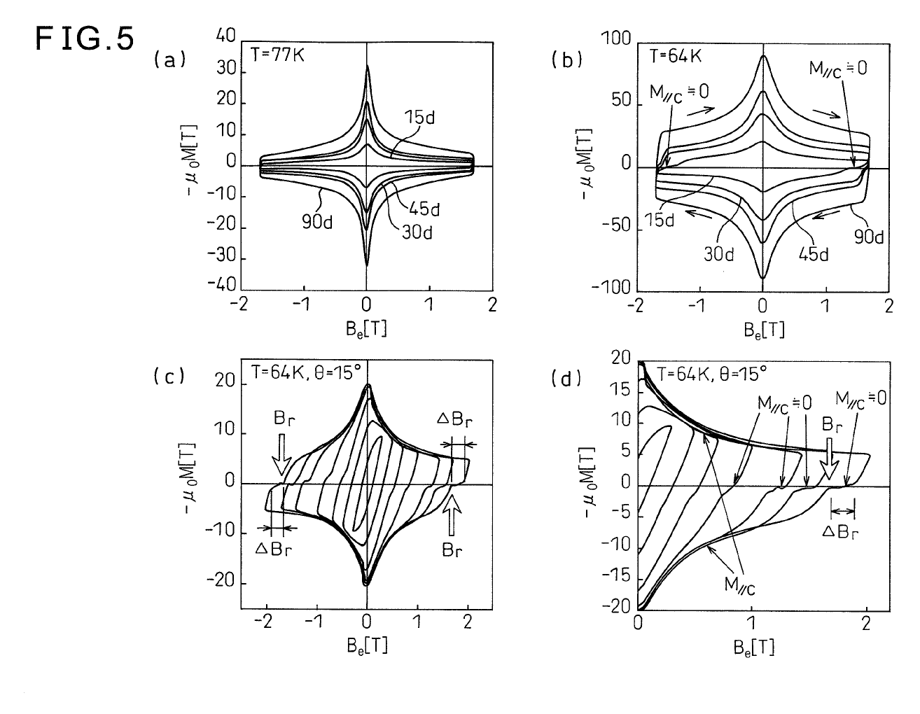

FIG. 5 shows the results of measurement of the magnetization properties of the test wire A at the maximum magnetic field amplitude Bm: 1.7T or 2.0T.

FIG. 5(a) shows the magnetization curves which were measured at T=77K, θ=90°, 45°, 30°, and 15°, and a maximum magnetic field amplitude Bm: 1.7T, while FIG. 5(b) shows the magnetization curves which were measured at T=64K, θ=90°, 45°, 30°, and 15°, and a maximum magnetic field amplitude Bm: 1.7T.

FIG. 5(c) shows the magnetization curve which was measured at T=64K, θ=15°, and maximum magnetic field amplitude Bm: 2.0T, while FIG. 5(d) shows the enlarged right end of the magnetization curve which was measured at T=64K, θ=15°, and a maximum magnetic field amplitude Bm: 2.0T. Note that, in FIG. 5(b), the arrows show the magnetization process.

It will be understood that, at the left and right ends of the magnetization curve shown in FIG. 5(b) (T=64K, θ=15°, maximum magnetic field amplitude Bm: 1.7T) (magnetization curve which is formed by intensity of external magnetic field turning from increase to decrease or from decrease to increase), there are “magnetization-zero-regions” near zero magnetization where the rate of change of the magnetization is substantially zero (in the figure, see M_{//c}≈0).

The presence of the “magnetization-zero-regions” can be seen more pronounced at the magnetization curves of the left and right ends of the magnetization curves shown in FIG. 5(c) and FIG. 5(d) (T=64K, θ=15°, maximum magnetic field amplitude Bm: 2.0T). In FIG. 5(c), the “magnetization-zero-region” is shown by ΔBr, while the magnetic field whereby the magnetization curve returns to the ordinary behavior is shown by Br.

That is, the inventors discovered that, in the temperature range where the superconducting phenomenon is manifested, there is a magnetization-zero-region where the magnetization curve which is formed by the intensity of the external magnetic field turning from an increase to a decrease or from a decrease to an increase has a rate of change of magnetization of substantially zero near zero magnetization.

This is a novel discovery relating to an RE₁Ba₂Cu₃O_{7-z} superconductor which the inventors discovered, that is, a discovery which should be called the “Iwakuma-Magnetization-Zero-Running effect (hereinafter sometimes referred to as the ‘IMZR effect’)”, and is a discovery forming the basis of the present invention.

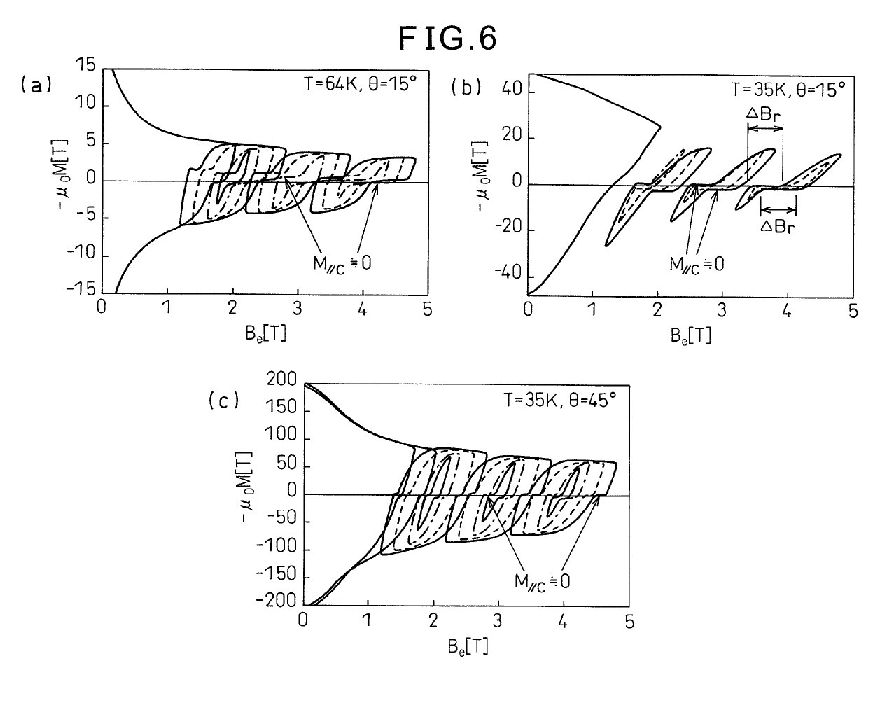

FIG. 6 shows the results of measurement of the magnetization properties of the test wire A in a 2T, 3T, and 4T DC bias magnetic field while changing the magnetic field amplitude Bm. FIG. 6(a) shows the magnetization curve which is measured at T=64K and θ=15°, FIG. 6(b) shows the magnetization curve which is measured at T=35K and θ=15°, and FIG. 6(c) shows the magnetization curve which is measured at T=35K and θ=45°.

As shown in FIG. 6(a) to (c), it will be understood that the lower the temperature and, further, the smaller the magnetic field application angle θ, the larger the ΔBr and the more pronounced the IMZR effect.

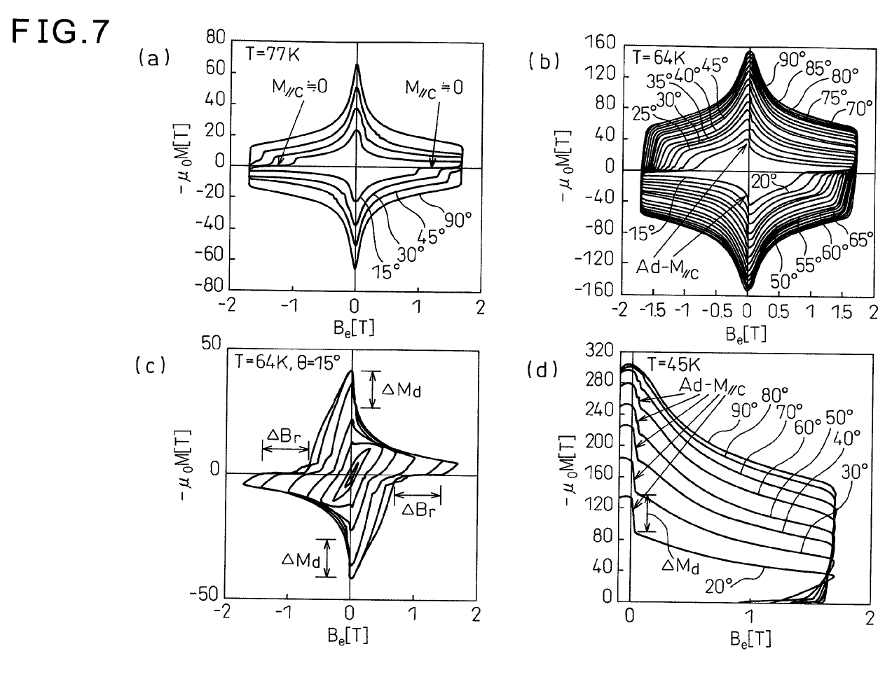

FIG. 7 shows the results of measurement of the magnetization properties of the test wire B at the maximum magnetic field amplitude Bm: 1.7T. FIG. 7(a) shows the magnetization curves of the test wire B which were measured at T=77K and θ=90°, 45°, 30°, and 15°, while FIG. 7(b) shows the magnetization curves of the test wire B which were measured at T=64K and θ=90°, 85°, 80°, 75°, 70°, 65°, 60°, 55°, 50°, 45°, 40°, 35°, 30°, 25°, 20°, and 15°.

FIG. 7(c) shows the magnetization curve which was measured at T=64K and θ=15°, while FIG. 7(d) shows the top rights of the magnetization curves which were measured at T=45K and θ=90°, 80°, 70°, 60°, 50°, 40°, 30°, and 20°.

It will be understood that, at the left and right ends of the magnetization curve shown in FIG. 7(a) (θ=45°, 30°, 15°) (magnetization curve which is formed by intensity of external magnetic field turning from increase to decrease or from decrease to increase), there are “magnetization-zero-regions” (in the figure, see M_{//c}≈0 (IMZR effect)).

FIG. 7(b) shows the magnetization curve in the case of lowering the temperature T of the test wire B from 77K to 64K. It is learned that the θ=15° magnetization curve has a magnetization abrupt drop zone where the magnetization abruptly drops when the external magnetic field reverses in direction (in the figure, see Ad-M_{//c} [Abrupt drop of M_{//c}]).

That is, the inventors discovered that, in the temperature range where the superconducting phenomenon is manifested, in the magnetization curve which is formed when an external magnetic field reverses in direction, there is a magnetization abrupt drop zone where the magnetization abruptly drops when the external magnetic field reverses in direction (in the figure, see Ad-M_{//c} [Abrupt drop of M_{//c}]. The Ad-M_{//c} zone, as shown in FIG. 7(d), sometimes being indicated by ΔMd).

This is a novel discovery relating to an RE₁Ba₂Cu₃O_{7-z} superconductor which the inventors discovered, that is, a discovery which should be called the “Iwakuma-Magnetization-Abrupt-Drop effect (below, sometimes also called the ‘IMAD effect’)”. This discovery is also a discovery forming the basis of the present invention.

The magnetization curve shown in FIG. 7(c) (T=64K, θ=15°) has both a ΔBr based on the IMZR effect (magnetization-zero-region) and an ΔMd (magnetization abrupt drop zone) based on the IMAD effect. The presence of the ΔMd (magnetization abrupt drop region), as shown by the magnetization curve shown in FIG. 7(d), becomes more pronounced the smaller the magnetic field application angle θ.

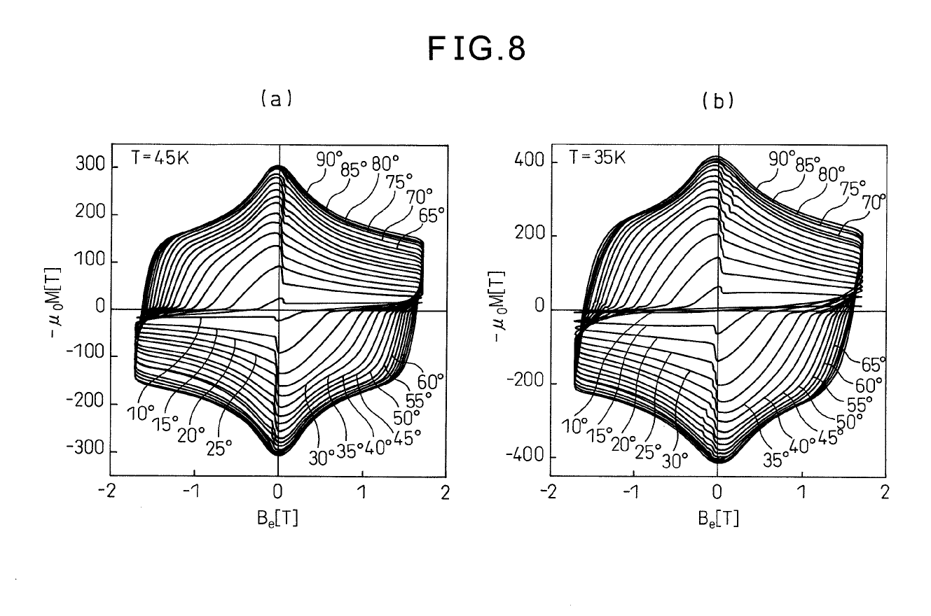

FIG. 8 shows the results of measurement of the magnetization properties of the test wire B at T=45K and 35K, a maximum magnetic field amplitude Bm: 1.7T, and a magnetic field application angle θ changed in the range of 10 to 90°. FIG. 8(a) shows the magnetization curve which is measured at T=45K, while FIG. 8(b) shows the magnetization curve which is measured at T=35K.

As shown in FIGS. 8(a) and (b), it is learned that the lower the temperature and, further, the smaller the magnetic field application angle θ, the larger the ΔBr and Mild and the more pronounced the IMZR effect and IMAD effect.

Furthermore, in FIGS. 8(a) and (b), if focusing on the θ=10° magnetization curve, it will be understood that the Br (magnetization-zero-region) and ΔMd (magnetization abrupt drop zonce) which appeared at 45K do not appear at 35K and that the magnetization curve exhibits a flat profile near the magnetization zero axis.

That is, the magnetization curve (x) has a magnetization-zero-region over the entire region of the curve or (y) becomes a magnetization curve which follows substantially the same magnetization path and does not swell much at all when the external magnetic field changes.

The above phenomenon of the magnetization curve flattening out in the superconducting temperature range (sometimes called the “Iwakuma magnetization-zero-flat (IMZF) phenomenon”) is also a specific phenomenon of an REBCO superconductor which the inventors discovered. The manifestation of the specific IMZF phenomenon is related to the superconducting mechanism of the superconducting layer. This will be explained later.

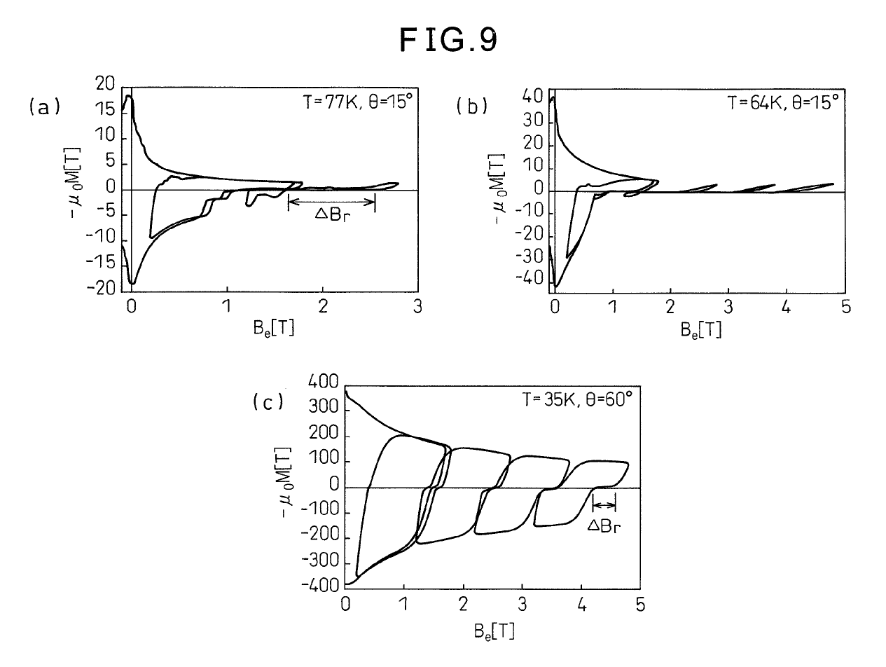

FIG. 9 shows the results of measurement of the magnetization properties of the test wire B in 1 to 4T DC bias magnetic fields at changed temperatures T and magnetic field application angles θ

FIG. 9(a) shows magnetization curves which are measured in DC bias magnetic fields 1T and 2T at T=77K and θ=15°, FIG. 9(b) shows magnetization curves which are measured in DC bias magnetic fields 1T, 2T, 3T, and 4T at T=64K and θ=15°, and FIG. 9(c) shows magnetization curves which are measured in DC bias magnetic fields 1T, 2T, 3T, and 4T at T=35K and θ=60°.

In FIG. 9, to show how the magnetization curve in the DC bias magnetic field is deformed from the magnetization curve shown in FIG. 7 which is measured by changing the external magnetic field about the zero magnetic field, the magnetization curve which is measured under a zero DC bias magnetic field is also shown.

From the figure, it is learned that the lower the temperature T, the more pronouncedly the ΔBr (magnetization-zero-region) is manifested and that, further, the higher the magnetic field Be, the greater the ΔBr (magnetization-zero-region).

The specific behavior of the magnetization curve which the inventors discovered is the great reduction in the area which is surrounded by the magnetization curve, so a great reduction in the pinning loss can be expected.

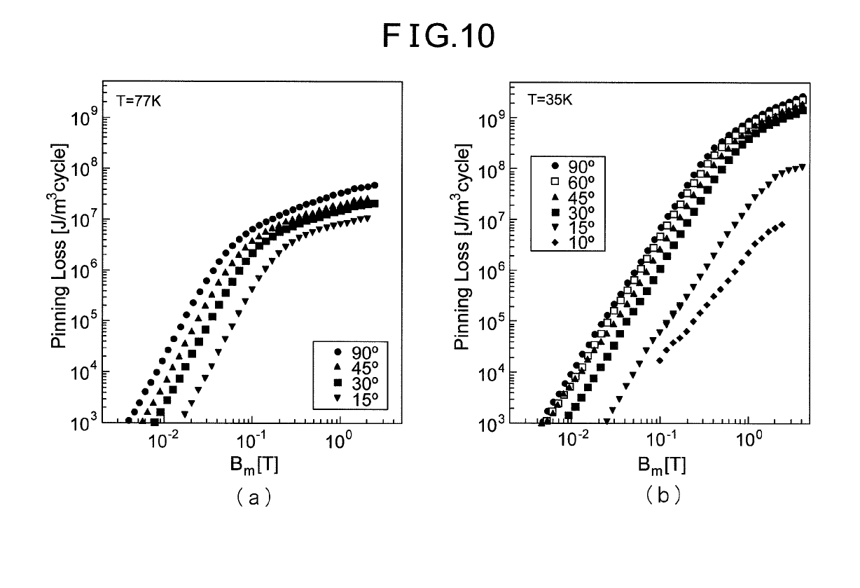

FIG. 10 shows the relationship, measured for the test wire A and the test wire B, between the magnetic field amplitude Bm(T) and the pinning loss (J/m³ cycle). FIG. 10(a) shows the results, measured for the test wire A, at T=77K and θ=90°, 45°, 30°, and 15° (corresponding to FIG. 5(a)), while FIG. 10(b) shows the relationship, measured for the test wire B, at T=35K and θ=90°, 60°, 45°, 30°, 15°, and 10° (corresponding to FIG. 8(b)).

As shown in FIG. 5(a), the magnetization curve at 77K of the test wire A shows the ordinary behavior. The pinning loss in this case matches the value predicted in the critical state model (see NPLT 7). In the pinning loss curve shown in FIG. 10(a), the magnetic field at the inflection point corresponds to the penetration field (Bp) where the magnetic flux penetrates to the center part of the superconducting layer of the wire.

In the region of Bm>Bp, if changing the magnetic field application angle θ, the pinning loss is reduced by sin θ compared with the pinning loss when θ=90°, that is, if the pinning loss for the magnetic field application angle θ is W(θ), W(θ)=W(90°)·sin θ.

On the other hand, the magnetization curve at 35K of the test wire B shows specific behavior (see FIG. 8(b). ΔBr(M_{//c}≈10) and ΔMd(Ad-M_{//c}) are present). The area surrounded by the magnetization curve corresponds to the pinning loss. The magnetization curve shown in FIG. 8(b) is deformed in a direction where the area surrounded is reduced compared with an ordinary magnetization curve, so the pinning loss is reduced.

In particular, the pinning loss when θ=15° and 10°, as shown in FIG. 10(b), is remarkably reduced. For example, at Bm=1T, W(15°)=( 1/13)W(90°)sin 15° and W(10°)=( 1/76)W(90°)sin 10°. Further, at Bm=2T, W(15°)=( 1/6.6)W(90°)sin 15° and W(10°)=( 1/45)W(90°)sin 10°.

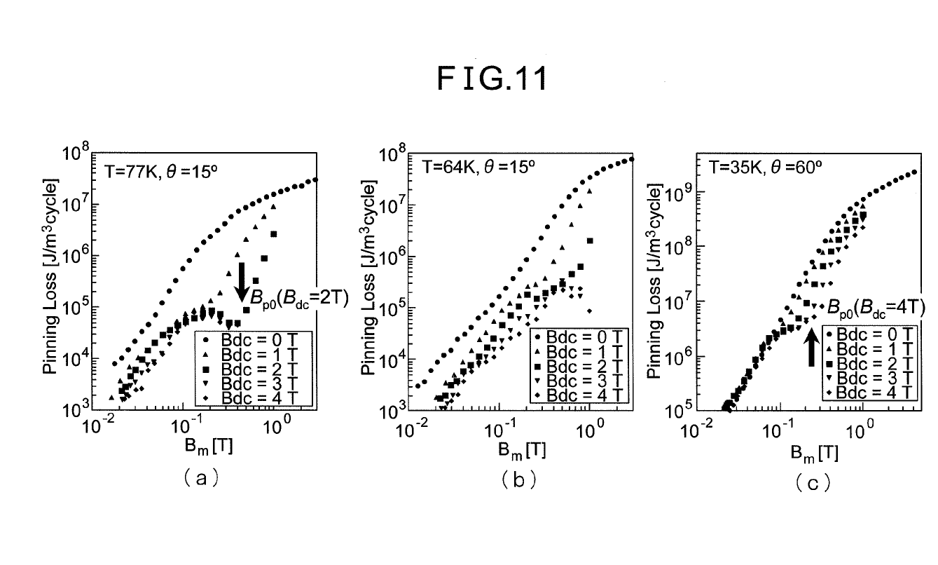

The reduction in the pinning loss in the DC bias magnetic field is more pronounced than the case of the AC magnetic field centered about the zero magnetic field. FIG. 11 shows the relationship, measured for the test wire B, of the magnetic field Bm (T) and the pinning loss (J/m³ cycle).

FIG. 11(a) shows the results of measurement at T=77K, θ=15° (corresponding to FIG. 9(a)), FIG. 11(b) shows the results of measurement at T=64K, θ=15° (corresponding to FIG. 9(b)), and FIG. 11(c) shows the results of measurement at T=35K, θ=60° (corresponding to FIG. 9(b)).

In the changes of the pinning loss in a DC magnetic field of 1 to 4T of the test wire B, there are two inflection points corresponding to the magnetization curve. The top inflection point corresponds to the penetration field Bp and, as shown in FIGS. 10(a) and (b), is the same as the magnetic field when Bdc=0T. On the other hand, at the bottom inflection point, the pinning loss rapidly increases.

Usually, the up and down magnetization difference (ΔM) in the magnetization curve corresponds (one-to-one) with the critical current density, but in the magnetization curve of the superconductor of the present invention, at the temperature range where the superconducting phenomenon is manifested, there is a ΔBr (M_{//c}≈0 magnetization-zero-region) and/or ΔMd (Ad-M_{//c} magnetization abrupt drop zone). In these zones, as explained above, the pinning loss (J/m³ cycle) greatly falls, so the magnetization difference (ΔM) of the magnetization zone of the present invention does not correspond (one-to-one) with the critical current density.

Further, the above magnetization difference (ΔM) does not correspond (one-to-one) to the wire width or the filament width when split into filaments.

In the magnetization curve of the RE₁Ba₂Cu₃O_{7-z} superconductor, the presence, in the temperature range where the superconducting phenomenon is manifested, of ΔBr (M_{//c}≈0 magnetization-zero-region) and/or ΔMd (Ad-M_{//c} magnetization abrupt drop zone) is closely related to the superconducting mechanism of the superconducting layer.

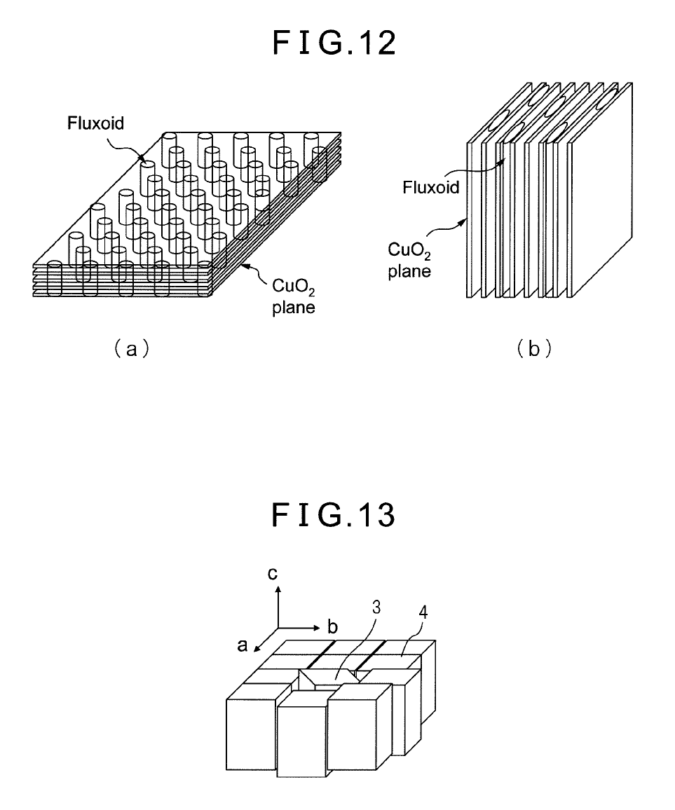

FIG. 12 schematically shows the mode of penetration of magnetic flux to the REBCO superconducting layer. FIG. 12(a) shows the mode of the quantized magnetic flux (fluxoid) penetrating the REBCO superconducting layer (CuO₂ plane) perpendicularly, while FIG. 12(b) shows the mode of the quantized magnetic flux (fluxoid) penetrating the REBCO superconducting layer in parallel.

The mode of penetration of the magnetic flux which is shown in FIG. 12(a) substantially corresponds to the mode of magnetization which magnetizes (M_{//c}) substantially along the c axis of the crystal which is shown in FIG. 4(a), while the mode of penetration of the magnetic flux which is shown in FIG. 12(b) substantially corresponds to the mode of magnetization which magnetizes (M_{//ab}) substantially along the a axis and the b axis of the crystal which is shown in FIG. 4(b).

In the state where the quantized magnetic flux penetrates substantially along the c axis of the crystal (passes through the CuO₂ planes) (see FIG. 12(a)), the quantized magnetic flux impairs the superconducting property of the CuO₂ planes. On the other hand, in the state where the magnetic flux penetrates in parallel between the REBCO superconducting layers (CuO₂ planes) (see FIG. 12(b)), the magnetic flux does not impair the superconducting property of the “CuO₂ plane”, so a magnetization curve which manifests the IMZF phenomenon such as the magnetization curve of θ=10° at 35K which is shown in FIG. 8(b) is realized.

The IMZF phenomenon is closely related to the crystallinity of the “CuO₂ planes”. FIG. 13 shows one aspect of alignment of superconducting crystals. Among the in-plane aligned crystal grains 4, if there are crystal grains 3 with an in-plane alignment angle Δφ, a region with a small critical current density Jc is formed. Therefore, Δφ≈0 is preferable.

As shown in Table 1, the test wire A has a Δφ of 5.4°, while the test wire B has a Δφ of 3.0°. Δφ is preferably less than 6.0°. More preferably, it is less than 4.0°, more preferably less than 3.0°.

From the above, the IMZR effect, IMAD effect, and IMZF phenomenon are believed to be manifested in accordance with the principle that the CuO₂ superconducting planes which are mainly responsible for transporting superconducting current mainly extend two dimensionally and are present in a plurality of planes at certain plane intervals and that having the magnetic flux or quantized magnetic flux penetrate between the CuO₂ planes results in a lower energy of the system and greater stability by the amount of difference of the superconducting condensation energy compared with having the quantized magnetic flux have a perpendicular component to the CuO₂ planes or enter perpendicular to or at a slant from the CuO₂ planes.

That is, in an RE₁Ba₂Cu₃O_{7-z} superconductor, it is believed that the phenomenon of a small magnetization and/or the phenomenon of a small pinning loss is manifested in accordance with the principle that the CuO₂ superconducting planes which are mainly responsible for transporting superconducting current mainly extend two dimensionally and are present in a plurality of planes at certain plane intervals and that having the magnetic flux or quantized magnetic flux penetrate between the CuO₂ planes results in a lower energy of the system and greater stability by the amount of difference of the superconducting condensation energy compared with having the quantized magnetic flux have a perpendicular component to the CuO₂ planes or enter perpendicular to or at a slant from the CuO₂ planes.

Above, the present invention was explained with reference to the example of RE₁Ba₂Cu₃O_{7-z} superconductors in the case where RE=Y and Gd (test wire A and test wire B), but RE may also be Y₁₋ₓGdₓ (0<x<1). Further, the IMZR effect and/or IMAD effect of the present invention is manifested if applying a magnetic field toward a higher magnetic field in the state cooling an RE₁Ba₂Cu₃O_{7-z} superconductor to a temperature range where the superconducting phenomenon is manifested, so RE is one or more of Y, Gd, Nd, Sm, Eu, Yb, Pr, and Ho.

Further, if predicated on the above principle, the present invention includes a superconductor wherein a phenomenon of a small magnetization and/or a phenomenon of a small pinning loss is manifested in accordance with the principle that the thin superconducting planes which are mainly responsible for transporting superconducting current mainly extend two dimensionally and are present in a plurality of planes at certain plane intervals and that having the magnetic flux or quantized magnetic flux penetrate between the superconducting planes results in a lower energy of the system and greater stability by the amount of difference of the superconducting condensation energy compared with having the quantized magnetic flux have a perpendicular component to the superconducting planes or enter perpendicular to or at a slant from the superconducting planes.

The method of production of the superconductor of the present invention will be explained next. A test wire A and a test wire B, as explained above, were produced using the RR method using the IBAD method and the PLD method (see NPLT 5). For this reason, a superconductor of the present invention with an RE of one or more of Y, Gd, Nd, Sm, Eu, Yb, Pr, and Ho can also be produced using the RR method. The conditions of the IBAD, PLD, and RR method are not particularly limited, but are preferably selected so as to enable the production of an RE₁Ba₂Cu₃O_{7-z} superconductor with good crystallinity (both small Δφ, Δω).

### Examples

Next, examples of the present invention will be explained. The conditions in the examples are just illustrations adopted for confirming the workability and advantageous effects of the present invention. The present invention is not limited to these illustrations. The present invention can employ various conditions so long as not departing from the gist of the present invention and achieving the object of the present invention.

### Examples

Using the RR method using the IBAD and PLD method, a test wire A and a test wire B shown in Table 1 were again produced. Note that, the test wire A had a Δφ of 5.3°, while the test wire B had a Δφ of 2.9°. In the two test wires, in the temperature range where the superconducting phenomenon is manifested, the cooling temperature, magnetic field, and rotation angle were changed and the magnetization properties measured. The measurement results were similar to the results shown in FIGS. 5 to 11.

### INDUSTRIAL APPLICABILITY

As explained above, according to the present invention, it is possible to provide an REBCO superconductor which enables the production of an REBCO superconducting wire with an extremely small magnetization and pinning loss in a fluctuating or stationary magnetic field. Accordingly, the present invention has a high industrial applicability in the superconducting equipment producing industry.

### REFERENCE SIGNS LIST

1. saddle-shaped pick-up coil
2. test wire
3. crystal grain with in-plane alignment angle Δφ
4. in-plane oriented crystal grain

1. A RE₁Ba₂Cu₃O_{7-z} superconductor characterized by having a magnetization-zero-region on its magnetization curve, wherein in the magnetization-zero-region a rate of change of magnetization remains at about zero near zero magnetization, the magnetization curve is formed when an external magnetic field turns from an increase to a decrease or from a decrease to an increase, and RE is one or more of Y, Gd, Nd, Sm, Eu, Yb, Pr, and Ho.

2. The RE₁Ba₂Cu₃O_{7-z} superconductor as set forth in claim 1 characterized in that a magnetization difference (ΔM) of said magnetization-zero-region does not correspond one-to-one to a magnitude of a critical current density, a wire width, or, when divided into filaments, a cumulative total of the filament widths.

3. The RE₁Ba₂Cu₃O_{7-z} superconductor as set forth in claim 1 or 2 characterized in that said magnetization curve has a magnetization abrupt drop zone in which the magnetization abruptly drops when the external magnetic field reverses in direction.

4. The RE₁Ba₂Cu₃O_{7-z} superconductor as set forth in claim 1 or 2 characterized in that said magnetization curve has said magnetization-zero-region extending over the entire curve.

5. The RE₁Ba₂Cu₃O_{7-z} superconductor characterized in that a phenomenon described in one or more of claim 1 or 2 becomes pronounced, whereby the magnetization curve does not swell much at all when the external magnetic field changes, that is, follows substantially the same magnetization path when the external magnetic field changes.

6. The RE₁Ba₂Cu₃O_{7-z} superconductor as set forth in any one of claim 1 or 2 characterized in that said RE is Gd.

7. The RE₁Ba₂Cu₃O_{7-z} superconductor as set forth in any one of claim 1 or 2 characterized in that said RE is Y.

8. The RE₁Ba₂Cu₃O_{7-z} superconductor as set forth in any one of claim 1 or 2 characterized in that said RE is Y₁₋ₓGdₓ (0<x<1).

9. The RE₁Ba₂Cu₃O_{7-z} superconductor as set forth in any one of claim 1 or 2 characterized in that an in-plane crystal alignment of said RE₁Ba₂Cu₃O_{7-z} superconductor is less than 6.0°.

10. The RE₁Ba₂Cu₃O₇₋ₓ superconductor as set forth in any one of claim 1 or 2 characterized in that the phenomena described one or more of claims 1 to 5 occurs in accordance with the principle that the CuO₂ superconducting planes which are mainly responsible for transporting superconducting current mainly extend two dimensionally and are present in a plurality of planes at certain plane intervals and that having the magnetic flux or quantized magnetic flux penetrate between the CuO₂ planes results in a lower energy of the system and greater stability by the amount of difference of the superconducting condensation energy compared with having the quantized magnetic flux have a perpendicular component to the CuO₂ planes or enter perpendicular to or at a slant from the CuO₂ planes.

11. A RE₁Ba₂Cu₃O_{7-z} superconductor characterized in that a phenomenon of a small magnetization and/or a phenomenon of a small pinning loss occurs in accordance with the principle that the CuO₂ superconducting planes which are mainly responsible for transporting superconducting current mainly extend two dimensionally and are present in a plurality of planes at certain plane intervals and that having the magnetic flux or quantized magnetic flux penetrate between the CuO₂ planes results in a lower energy of the system and greater stability by the amount of difference of the superconducting condensation energy compared with having the quantized magnetic flux have a perpendicular component to the CuO₂ planes or enter perpendicular to or at a slant from the CuO₂ planes.

12. A superconductor characterized in that a phenomenon of a small magnetization and/or a phenomenon of a small pinning loss occurs in accordance with the principle that the thin superconducting planes which are mainly responsible for transporting superconducting current mainly extend two dimensionally and are present in a plurality of planes at certain plane intervals and that having the magnetic flux or quantized magnetic flux penetrate between the superconducting planes results in a lower energy of the system and greater stability by the amount of difference of the superconducting condensation energy compared with having the quantized magnetic flux have a perpendicular component to the superconducting planes or enter perpendicular to or at a slant from the superconducting planes.
